(19) United States
(12) Patent Application Publication
(10) Pub. No.: US 2018/0331189 A1
(43) Pub. Date: Nov. 15, 2018

(54) Electron Carrier Confinement in Gallium Oxide (Ga2O3)

(71) Applicant: Government of the United States, as represented by the Secretary of the Air Force, Wright-Patterson AFB, OH (US)

(72) Inventor: Eric R. Heller, Kettering, OH (US)

(21) Appl. No.: 15/976,554

(22) Filed: May 10, 2018

Related U.S. Application Data
(60) Provisional application No. 62/506,202, filed on May 15, 2017.

(51) Int. Cl. H01L 29/24; H01L 41/18; H01L 29/778; H01L 29/20

(52) U.S. Cl. CPC H01L 29/24; H01L 29/2003; H01L 29/7786; H01L 41/183

(57) ABSTRACT

An electronic device is provided including an electrode, a Gallium Oxide (Ga₂O₃) semiconducting layer, and a dielectric layer positioned in physical contact with the Gallium Oxide (Ga₂O₃) semiconducting layer, and a negative sheet charge is formed at an interface between the dielectric layer and Gallium Oxide (Ga₂O₃) semiconducting layer. The negative sheet charge repels electrons and raises the conduction band above the Fermi level to reduce electron penetration into the dielectric layer.

### CROSS-REFERENCE TO RELATED APPLICATIONS

This application claims the benefit of and priority to U.S. Provisional Application Ser. No. 62/506,202, entitled “Electron Carrier Confinement in Gallium Oxide Power Switches,” filed on May 15, 2017, the entirety of which is incorporated by reference herein.

RIGHTS OF THE GOVERNMENT

The invention described herein may be manufactured and used by or for the Government of the United States for all governmental purposes without the payment of any royalty.

### BACKGROUND OF THE INVENTION

### Field of the Invention

The present invention generally relates to electronic devices (discrete or for integrated circuits) and, more particularly, to electron carrier confinement in Gallium Oxide (Ga₂O₃) devices.

### Description of the Related Art

SiC and GaN power devices have attracted much attention as key components for high-efficiency power conversion. Their device performance can far exceed that of the Si-based devices mainly used in current power electronics. However, while performance of SiC and GaN based devices is good, they are not the only candidates for next-generation power devices. For example, Gallium oxide (Ga₂O₃) has gained increased attention for power devices due to its superior material properties and the availability of economical device quality native substrates. The material possesses excellent properties such as a large band gap of 4.7-4.9 eV with an estimated high breakdown field of 8 MV/cm.

While Gallium Oxide is a promising new material with an ultra-wide bandgap, as the bandgap of a material increases, it becomes harder to keep the electrons in the material. The conventional approach to keep the electrons in the Ga₂O₃ material is to use a material with a higher conduction band edge than the underlying material (here, Ga₂O₃). But, finding a dielectric with a higher conduction band than Ga₂O₃ that also satisfies the other needed properties (high breakdown field, high electrical interface quality) is challenging.

Accordingly, there is a need in the art for a passivation layer that can both withstand the huge electric fields Ga₂O₃ will withstand, keep the electrons in the underlying material and has suitable electronic properties.

### SUMMARY OF THE INVENTION

Embodiments of the invention address the need in the art by providing an electronic device, which includes an electrode, a semiconducting layer, a dielectric layer positioned between and in contact with the electrode and the semiconducting layer, and a negative sheet charge formed at an interface between the dielectric layer and the semiconducting layer. The negative sheet charge repels electrons and raises a conduction band. In some embodiments of the electronic device, the semiconducting layer comprises Gallium Oxide (Ga₂O₃). In some of these embodiments the dielectric layer may be piezoelectric III-V material. In other embodiments the dielectric layer may be a III-V material with spontaneous electric polarization. In some specific embodiments, the dielectric layer may selected from crystalline N-polar AlGaN, GaN, or AlN. In these specific embodiments, the N-polar AlGaN, GaN, or AlN may be oriented with the c-axis perpendicular to the growth plane.

Additional objects, advantages, and novel features of the invention will be set forth in part in the description which follows, and in part will become apparent to those skilled in the art upon examination of the following or may be learned by practice of the invention. The objects and advantages of the invention may be realized and attained by means of the instrumentalities and combinations particularly pointed out in the appended claims.

### BRIEF DESCRIPTION OF THE DRAWINGS

The accompanying drawings, which are incorporated in and constitute a part of this specification, illustrate embodiments of the invention and, together with a general description of the invention given above, and the detailed description given below, serve to explain the invention.

FIG. 1 is a schematic diagram of a Prior Art Device;

FIG. 2 is a schematic diagram of an embodiment of the invention;

FIG. 3 contains a plot of electron density in the Prior Art Device of FIG. 1 in a key region between the gate and the drain;

FIG. 4 contains a plot of electron density in the embodiment of FIG. 2 in a key region between the gate and the drain;

FIG. 5 contains a plot of conduction band energy in the Prior Art Device of FIG. 1 in a key region between the gate and the drain;

FIG. 6 contains a plot of conduction band energy in the embodiment of FIG. 2 in a key region between the gate and the drain; and

FIG. 7 contains a plot of conduction band energy vs. depth into the surface of the device.

It should be understood that the appended drawings are not necessarily to scale, presenting a somewhat simplified representation of various features illustrative of the basic principles of the invention. The specific design features of the sequence of operations as disclosed herein, including, for example, specific dimensions, orientations, locations, and shapes of various illustrated components, will be determined in part by the particular intended application and use environment. Certain features of the illustrated embodiments have been enlarged or distorted relative to others to facilitate visualization and clear understanding. In particular, thin features may be thickened, for example, for clarity or illustration.

### DETAILED DESCRIPTION OF THE INVENTION

Gallium Oxide (Ga₂O₃) is a new ultra-wide bandgap material with potential for power conversion and RF applications. A challenge with using Ga₂O₃ for these applications is that as the bandgap of a material increases, it becomes harder to keep the electrons in the material. For example, an n-type field effect transistor (FET) uses the electric field generated by a negative voltage on a gate to block the flow of electrons in a channel between two conductors to turn the transistor off. Where this flow is blocked there will be a high electric field in a FET that is used for high voltage blocking applications. For today's Ga₂O₃ FETs, the electrons reach to the top surface at either side of this blocked region. Contemporary practice is to have a dielectric between the source (S), gate (G), and drain (D) and the Ga₂O₃ with significantly higher conduction band to block the electrons from getting out, where a lower conduction band will allow them to go around the blocked region through the dielectric. Optionally, the source (S), gate (G), and drain (D) might be recessed into the dielectric and sometimes some of the underlying material (e.g. by lithographically etching or initially lithographically blocking deposition of these layers) for improved performance. This does not change the fundamental nature of the invention.

Thus, a passivation layer is needed that can withstand the huge electric fields Ga₂O₃ will withstand, keep the electrons in the material, and supply other various restraints such as not excessively cause electron scattering and is compatible with the device fabrication process (e.g. does not require extreme temperatures that can damage the rest of the device, does not contaminate the rest of the device or the deposition chamber, can be deposited in a reasonable time, can be etched where necessary, etc.). This need is most acute in the channel “depletion region” between the gate and drain of a field effect device or the depletion region of a diode, both of which may sustain high electric fields.

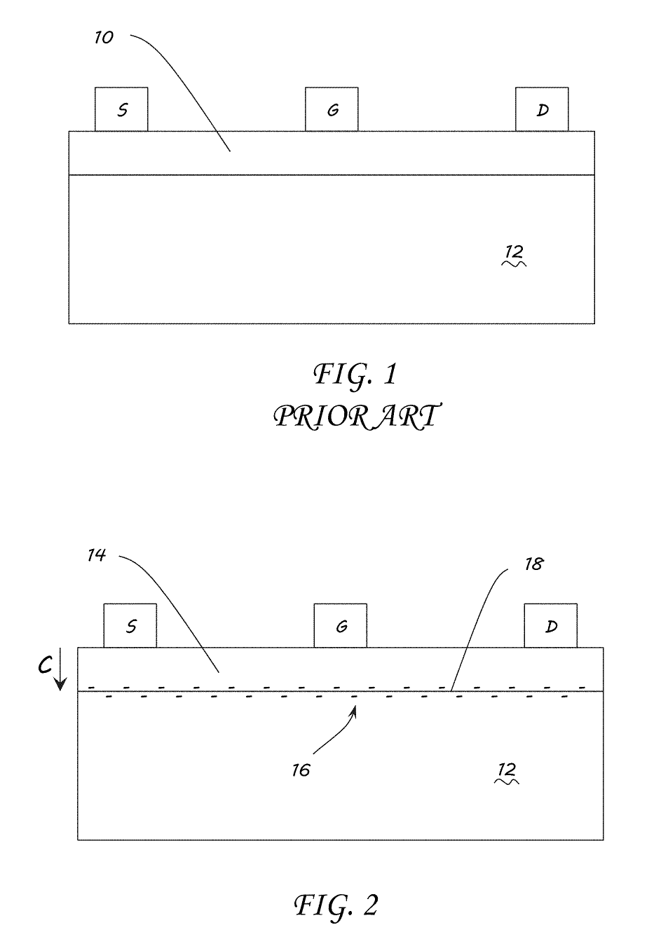

As set out above, contemporary approaches, such as that illustrated in FIG. 1, keep the electrons in the Ga₂O₃ material by using a material 10 with a higher conduction band edge than the underlying material 12, here, Ga₂O₃. A downside to this approach is that the requirement of the dielectric to have a higher conduction band than Ga₂O₃ eliminates a lot of good choices for a dielectric.

Embodiments of the invention provide an alternative to the contemporary approach by utilizing a passivation material 14 with spontaneous electric polarization (Aluminum Gallium Nitride or one of the binary endpoints) instead of the high conduction band material 10, which may be oriented to put negative sheet charge 16 at the passivation/Ga₂O₃ interface 18 as seen in FIG. 2. This sheet charge will repel electrons and thus raise the conduction band above the Fermi level, confining the electrons without the need for higher conduction band edge than the underlying material. Additionally, embodiments of the invention assist in relaxing the need for a high “quality” (e.g. low trapping and scattering of electrons) dielectric/underlying semiconductor interface because the electrons are repelled from reaching this interface.

Materials with piezoelectric and/or spontaneous electric polarization and with a negative charge layer at the dielectric/Ga₂O₃ interface 18 may be used to block the electrons before they get to the dielectric/Ga₂O₃ interface 18. Crystalline N-polar AlGaN, GaN or AN oriented with the c-axis perpendicular to the growth plane are examples of materials that would do this. Though, any material that can provide negative charge layer at the dielectric/Ga₂O₃ interface 18 would be a valid substitution. Additionally, in some embodiments, a layer of a conventional dielectric (without piezoelectric or spontaneous electric polarization) may also be put on top of the novel layer.

The c-axis can be perpendicular to the growth plane and lattice match can help but in a broader sense does not strictly have to be. The crux of the matter is that the sum of the spontaneous and piezoelectric polarization in the III-V material should induce a sheet of negative charge at the Ga₂O₃/III-V interface. N-face AlGaN with c-axis perpendicular to the growth plane is an exemplary configuration for a specific embodiment of the invention. In this exemplary embodiment, the AlGaN causes a charge barrier at the interface 18 with the Ga₂O₃ due to a lattice mismatch and due to the spontaneous polarization of AlGaN.

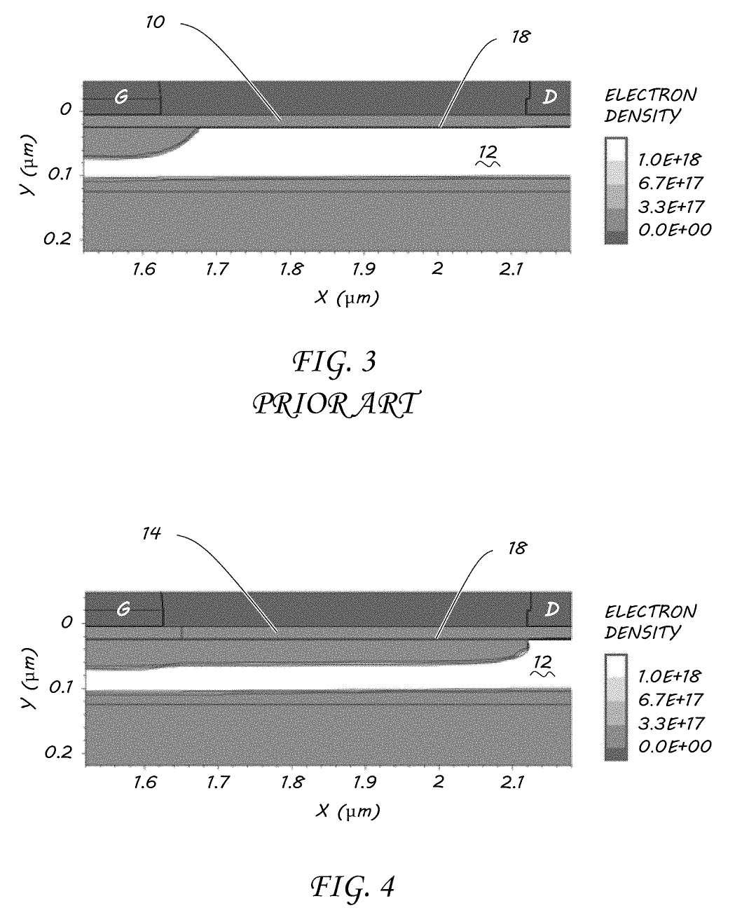

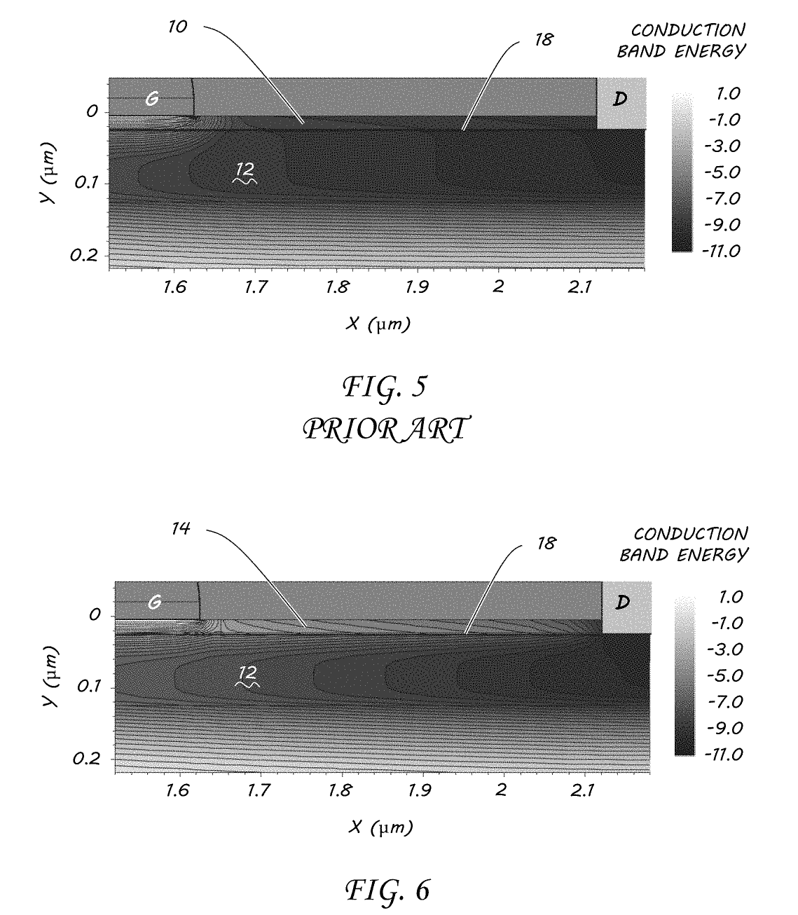

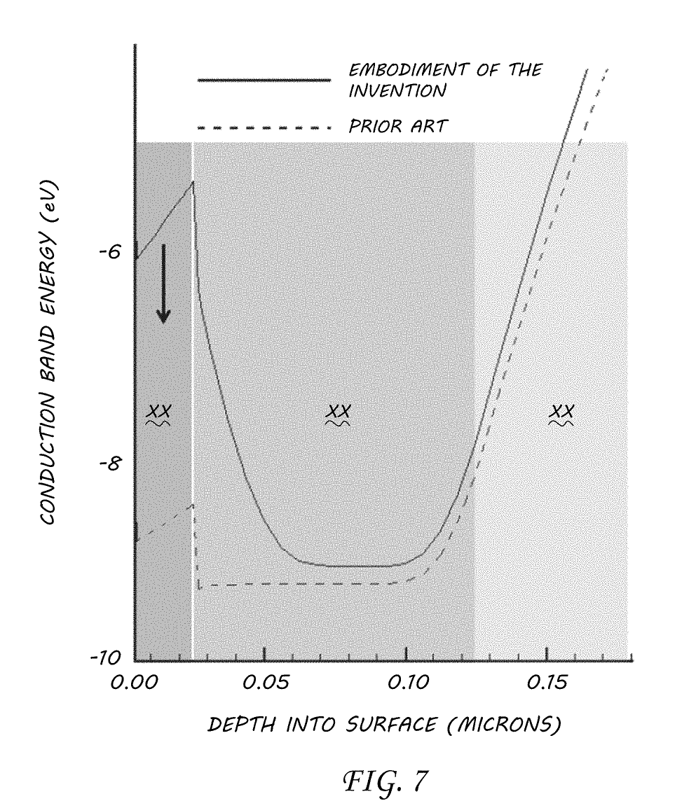

FIGS. 3 and 4 compare physics based device modeling of the prior art vs. an embodiment of the invention. They show the region of a field effect transistor between containing the gate and drain and the important high field “depletion” or “drift” region. The key difference is that the dielectric 10 in FIG. 3 is unpolarized while the dielectric has induced approximately 1×10¹³ cm⁻² negative charge at interface 18 for FIG. 4 between the dielectric 14 and the semiconductor 12, here represented as Ga₂O₃. The compared devices are in both cases in a partially “on” state at the same voltage conditions. FIGS. 5 and 6 show the exact same thing as FIGS. 3 and 4 respectively except for what is plotted. FIG. 7 shows a band-edge diagram vertically through the layers 10/14 and 12 and the semi-insulating substrate material below that (not numbered) for the same two simulations run and described above.

While the present invention has been illustrated by a description of one or more embodiments thereof and while these embodiments have been described in considerable detail, they are not intended to restrict or in any way limit the scope of the appended claims to such detail. Additional advantages and modifications will readily appear to those skilled in the art. The invention in its broader aspects is therefore not limited to the specific details, representative apparatus and method, and illustrative examples shown and described. Accordingly, departures may be made from such details without departing from the scope of the general inventive concept.

What is claimed is:

1. An electronic device, comprising:
an electrode;
a semiconducting layer;
a dielectric layer positioned in physical contact with the semiconducting layer and the electrode; and
a negative sheet charge formed at an interface between the dielectric layer and the semiconducting layer,
wherein the negative sheet charge repels electrons and raises a conduction band.

2. The electronic device of claim 1, wherein the semiconducting layer comprises Gallium Oxide (Ga₂O₃).

3. The electronic device of claim 1, wherein the dielectric layer is piezoelectric III-V material.

4. The electronic device of claim 1, wherein the dielectric layer is a III-V material with spontaneous electric polarization.

5. The electronic device of claim 1, wherein the dielectric layer is selected from crystalline N-polar AlGaN, GaN, or AlN.

6. The electronic device of claim 5, wherein the N-polar AlGaN, GaN, or AlN is oriented with the c-axis perpendicular to a growth plane.
